(19) United States
(12) Patent Application Publication
(10) Pub. No.: US 2022/0416753 A1
(43) Pub. Date: Dec. 29, 2022

(54) METHOD OF IMPEDANCE MATCHING, ELECTRONIC DEVICE AND COMPUTER-READABLE RECORDING MEDIUM

(71) Applicant: SAMSUNG ELECTRONICS CO., LTD., Suwon-Si (KR)

(72) Inventor: SU MIN KIM, Hwaseong-Si (KR)

(21) Appl. No.: 17/809,212

(22) Filed: Jun. 27, 2022

(30) Foreign Application Priority Data
Jun. 28, 2021 (KR) 10-2021-0083917

(51) Int. Cl. H03H 7/38; G01R 31/28

(52) U.S. Cl. CPC H03H 7/38; G01R 31/2812

(57) ABSTRACT

A method of designing an impedance matching circuit for an input circuit is provided. The method includes receiving a user input identifying a section of the input circuit for matching an impedance to generate a characteristic impedance value; dividing the section into a first portion and a second portion; determining a first partial matching circuit of the first portion and a second partial matching circuit of the second portion using component information about electrical components connected to the section and the generated characteristic impedance value; and combining the first partial matching circuit and the second partial matching circuit to generate an ideal matching circuit.

### CROSS-REFERENCE TO RELATED APPLICATION

This application claims priority under 35 U.S.C. § 119 to Korean Patent Application No. 10-2021-0083917 filed on Jun. 28, 2021 in the Korean Intellectual Property Office, the disclosure of which is incorporated by reference herein in its entirety.

### TECHNICAL FIELD

The present invention relates to a method of impedance matching, an electronic device, and a computer-readable recording medium.

### DISCUSSION OF THE RELATED ART

Electronic devices today are used for many different purposes. In order to provide the necessary functionality, various types of electronic components are placed inside the electronic devices. The electronic components inside the electronic devices may transmit signals through transmission paths. For example, components may be organized in many different ways, such as by mounting them directly on a printed circuit board, or mounting them on each other (package on package). In circuits of radio-frequency emitting components which may operate in high and diverse frequency bands, it is especially important to prevent unwanted signal interaction, such as signal reflection or destructive interference.

Accordingly, there is a need for precise impedance matching in electronic components, which eliminates a reflection loss when connecting two circuits.

### SUMMARY

Aspects of the present invention provide a method of impedance matching including a matching method using a transmission path, and a method of impedance matching using a lumped element. Aspects of the methods and systems of impedance matching disclosure herein provide increased convenience and efficiency, and reduced designing time during production. For example, embodiments of the present invention include a database of pre-existing circuits and electrical components and corresponding properties thereof, as well as methods for choosing a matching circuit between components, modeling an entire circuit with the matching circuit disposed between the components, dividing the entire circuit into two portions around a center (e.g., a center containing the matching circuit), and simulating different arrangement of the circuits to determine a best model for the circuit.

Aspects of the present invention also provide an electronic device including an impedance matching program having an increased efficiency and reduced designing time.

Aspects of the present invention also provide a computer-readable recording medium including an impedance matching program having an increased efficiency and reduced designing time.

A method for designing an impedance matching circuit for an input circuit according to aspects of the present disclosure includes receiving a user input identifying a section of the input circuit for matching an impedance to generate a characteristic impedance value; dividing the section into a first portion and a second portion; determining a first partial matching circuit of the first portion and a second partial matching circuit of the second portion using component information about electrical components connected to the section and the generated characteristic impedance value; and combining the first partial matching circuit and the second partial matching circuit to generate an ideal matching circuit.

An electronic device according to aspects of the present disclosure includes: a storage device storing an impedance matching program comprising a set of computer-readable instructions; and a processor configured to execute the impedance matching program stored in the storage device, wherein the impedance matching program includes: a characteristic impedance simulation module configured to parse a user input, the input including an input circuit and identifying a section including a real matching circuit in the input circuit for matching an impedance to determine a characteristic impedance value of the section based on the user input, and a calculation module configured to calculate an ideal matching circuit, wherein calculating the ideal matching circuit includes: dividing the section into a first portion and a second portion, generating a first partial matching circuit of the first portion and a second partial matching circuit of the second portion, using component information of electrical components connected to the section and the characteristic impedance value of the section, and combining the first partial matching circuit and the second partial matching circuit to calculate the ideal matching circuit.

A computer-readable recording medium according to aspects of the present disclosure includes program instructions embodied therewith, the program instructions executable by a processor to cause the processor to: calculate, by a simulation module, a characteristic impedance value of a section including a real matching circuit in an input circuit using information about the section, for matching an impedance; and calculate, by a calculation module included within an impedance matching program, an optimization matching value, wherein the calculation of the optimization matching value performed by the calculation module includes: dividing the section into a first portion and a second portion, determining a first partial matching circuit of the first portion and a second partial matching circuit of the second portion, using component information about electrical components connected in the section and a characteristic impedance value of the section, combining the first partial matching circuit and the second partial matching circuit to generate an ideal matching circuit, and calculating the optimization matching value using the ideal matching circuit and the real matching circuit.

### BRIEF DESCRIPTION OF THE DRAWINGS

FIG. 1 is a diagram that illustrates an impedance matching system according to some embodiments.

FIG. 2 is a diagram that illustrates a user input of FIG. 1.

FIG. 3 is a diagram that illustrates a database of FIG. 1.

FIG. 4 is a diagram that illustrates a calculation module of FIG. 1.

FIG. 5 is a flowchart that illustrates an impedance matching operation according to some embodiments.

FIG. 6 is a flowchart that illustrates the operation of generating the characteristic impedance value according to some embodiments.

FIG. 7 is a flowchart that illustrates the operation of generating the ideal matching circuit according to some embodiments.

FIG. 8 is a diagram that illustrates a step of generating a partial matching circuit of FIG. 7.

FIG. 9 is a flowchart that illustrates a step of generating the ideal matching circuit of FIG. 7.

FIGS. 10 to 13 are diagrams that illustrates the ideal matching circuit.

FIG. 14 is a flowchart that illustrates the operation of calculating the optimization matching value according to some embodiments.

FIG. 15 is a diagram that illustrates the operation of removing a part of the ideal matching circuit.

FIG. 16 is a diagram that illustrates an impedance matching automation system according to some embodiments.

FIG. 17 is a diagram that illustrates the simulation module of FIG. 16.

FIG. 18 is a flowchart that illustrates an impedance matching operation according to some embodiments.

FIG. 19 is a flowchart that illustrates an operation that simulates the reliability of the optimization matching value of FIG. 18.

FIG. 20 is a diagram that illustrates an impedance matching automation system according to some embodiments.

FIG. 21 is a diagram that illustrates the calculation module of FIG. 20.

### DETAILED DESCRIPTION OF THE EMBODIMENTS

Hereinafter, embodiments of the present inventive concept will be explained in detail with reference to the accompanying drawings.

Throughout the specification, like reference symbols in the drawings may denote like elements, and to the extent that a description of an element has been omitted, it may be understood that the element is at least similar to corresponding elements that are described elsewhere in the specification.

The various modules described herein may be implemented as separate or combined circuits, system-on-chips, packages, or sets of instructions stored in a non-transitory memory, e.g., stored on a memory device. Examples of memory devices include solid state memory and a hard disk drive. The memory may be used to store computer-readable, computer-executable software including instructions that, when executed, cause a processor to perform various functions described herein. The instructions may be implementations in a programming language, including compiled languages such as C++, and interpreted languages such as Python.

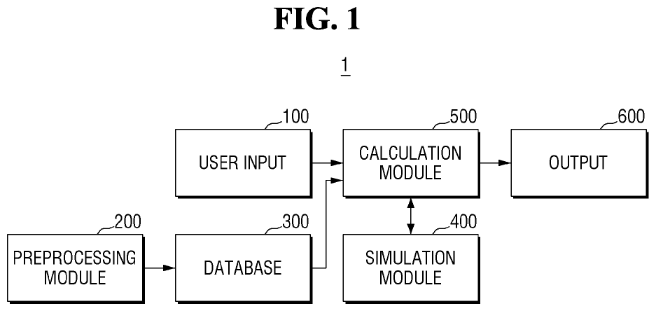

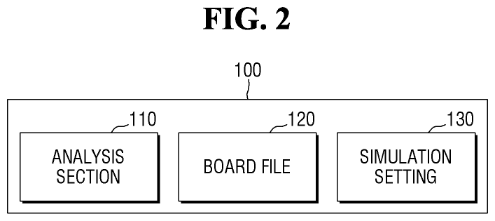

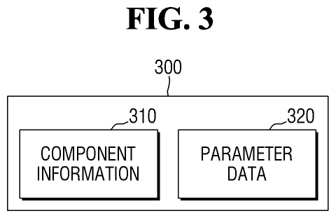

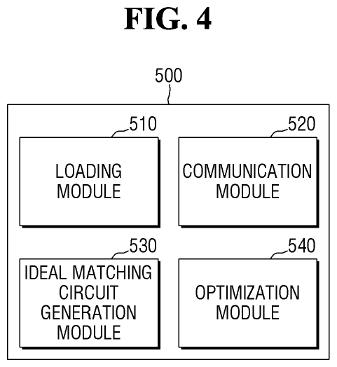

FIG. 1 is a diagram that illustrates an impedance matching system according to some embodiments. FIG. 2 is a diagram that illustrates a user input of FIG. 1. FIG. 3 is a diagram that illustrates a database of FIG. 1. FIG. 4 is a diagram that illustrates a calculation module of FIG. 1.

Referring to FIGS. 1 to 4, an impedance matching automation system 1 may include a preprocessing module 200, a database 300, a simulation module 400 and a calculation module 500.

Although an impedance matching circuit designed by the impedance matching system 1 according to some embodiments may be, for example, an impedance matching circuit applied to a printed circuit board (PCB), this is merely one embodiment, and other embodiments are not necessarily limited thereto. For the convenience of the description, an impedance matching circuit applied to the printed circuit board (PCB) will be described below as an example.

The impedance matching system 1 may be provided with a user input 100.

The user input 100 may include an analysis section 110, board file 120 and a simulation setting 130. The impedance matching system 1 may perform an impedance matching analysis on the basis of the user input 100.

The analysis section 110 may include information pertaining to impedance matching analysis. The information may include a section or area in which the impedance matching analysis is performed by the impedance matching system 1, for example, an area in which a real matching circuit designed to match the impedance is placed. For example, the analysis section 110 may include a real matching circuit, a transmission path connected to the real matching circuit, and a section to which the component to which the real matching circuit is connected through the transmission path corresponds. This information may be variously represented, for example, as a model or object in code, enumerated data, etc. Specifically, the analysis section 110 may include information about a physical size of a portion in which the real matching circuit is designed between the transmission paths (e.g., a length of the section in which the real matching circuit is placed in the PCB). Also, the analysis section 110 may include information for identifying a transmission path to be analyzed for the impedance matching among a plurality of transmission paths.

The board file 120 may include information about wiring (hereinafter, the transmission path) connected to the impedance matching circuit. For example, the user may input information about which component the transmission path included in the analysis section 110 is connected to, as the board file 120. In another example, the board file 120 may include information about which layer the transmission path is placed in, when the printed circuit board (PCB) is made up of a plurality of layers.

The simulation setting 130 may include information about the section or area which is simulated by the simulation module 400. For example, the user may input a specific section or area of the printed circuit board (PCB) into the simulation setting 130 to limit the section or area that is simulated by the simulation module 400. For example, the range information may include spatial range information, or other configurable parameters of the circuit.

The simulation setting 130 may adjust the speed and accuracy of the operation of the simulation module 400. In an embodiment, when the simulation setting 130 is input so as to model a wide area, as the simulation module 400 performs the simulation operation of a wide area, the operation of the simulation module 400 is accurate, but the speed may be slow. In another embodiment, when the simulation setting 130 is input so as to model a small area, as the simulation module 400 performs the simulation operation in the small area, the operation of the simulation module 400 is less accurate, and the speed may increase. According to the embodiment, the user may selectively input the simulation setting 130.

The preprocessing module 200 may preprocess the information stored in the database 300, for example, to process the information to have a format that may be used in the system. For example, the preprocessing module 200 may preprocess information that was a format of a data sheet to generate component information 310 so that the component information 310 stored in the database 300 has a format that may be used in the calculation module 500.

The database 300 may store the information used in the simulation module 400 and the calculation module 500. For example, the database 300 may store the component information 310 and the parameter data 320.

The component information 310 may include information about components to which transmission paths for matching impedances are connected. For example, the component information 310 may include information about electronic components including active elements or passive elements mounted on the printed circuit board (PCB) and connected to the transmission path.

The parameter data 320 may include information on variables that affect the impedance value of the transmission path. For example, the parameter data 320 may include information on an S parameter (scattering parameter).

The simulation module 400 may simulate and calculate the characteristic impedance value of the transmission path to which the impedance matching is applied, based on the analysis section 110 and the board file 120. The simulation module 400 may simulate the characteristic impedance value based on the command received from the calculation module 500. Further, when the user inputs the simulation setting 130, the simulation module 400 may simulate the characteristic impedance value within in the section or area corresponding to the simulation setting 130.

The calculation module 500 generates an ideal matching circuit using the characteristic impedance value of the transmission path calculated by the simulation module 400 and the component information 310, and may calculate an optimization matching value as a result, e.g. the output 600. The calculation module 500 may include a loading module 510, a communication module 520, an ideal matching circuit generation module 530, and an optimization module 540.

The loading module 510 may receive the component information 310 and the parameter data 320 stored in the database 300. Specifically, the loading module 510 may call the data stored in the database 300 to the calculation module 500 for use in the impedance matching system 1.

The communication module 520 may send commands so that the simulation module 400 calculates the characteristic impedance value. Further, the communication module 520 may receive the characteristic impedance value calculated by the simulation module 400. For example, the communication module 520 may provide communication between the calculation module 500 and the simulation module 400. According to the embodiments, a language through which the communication module 520 communicates with the simulation module 400 may be changed to a language compatible with the simulation module 400.

The ideal matching circuit generation module 530 may generate an ideal matching circuit of the area corresponding to the analysis section 110, using the component information 310 and the characteristic impedance value calculated by the simulation module 400. Specifically, the ideal matching circuit generation module 530 may generate a virtual ideal matching circuit to which the impedance may be matched when designed in the area including the real matching circuit. For example, the ideal matching circuit generation module 530 may generate an ideal matching circuit represented in data, with all the necessary information to fabricate the ideal matching circuit.

The optimization module 540 compares the ideal matching circuit generated by the ideal matching circuit generation module 530 with the real matching circuit, and may calculate the optimization matching value as the result, e.g., the output 600. The optimization module 540 may calculate a matching value that enables the ideal matching circuit to be implemented, for example, reproduced on a printed circuit board and/or package. For example, the optimization matching value may include a value that may be applied to the real matching circuit among the ideal matching values that are element values that the lumped element (LE) included in the ideal matching circuit may have. For example, if the lumped element (LE) contained in the real matching circuit is a capacitor, the optimization matching value may be a value that indicates the capacitance of the capacitor. In another example, when the lumped element (LE) included in the real matching circuit is an inductor, the optimization matching value may be a value indicating the inductance of the inductor.

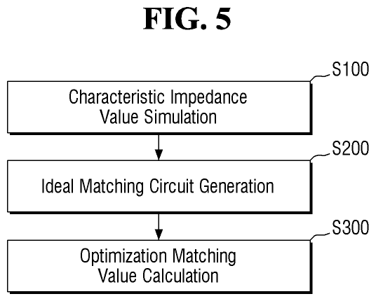

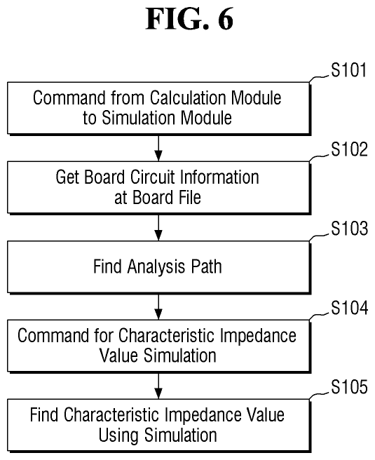

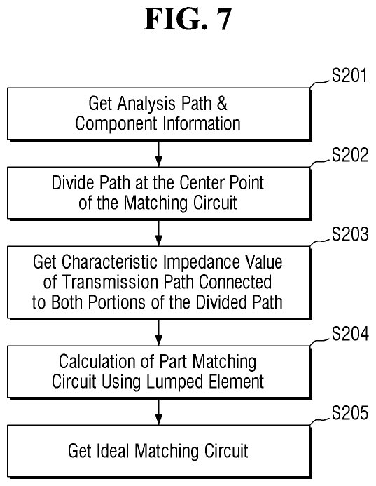

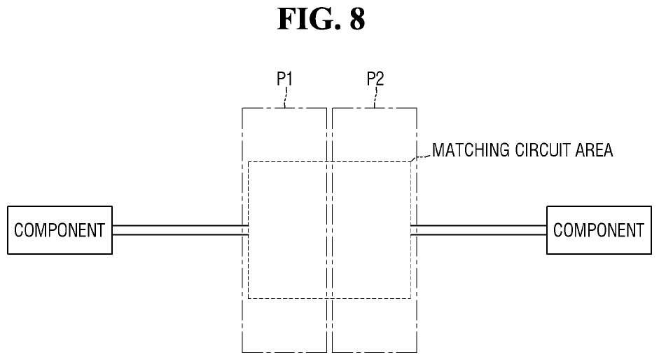

FIG. 5 is a flowchart that illustrates an impedance matching operation according to some embodiments. FIG. 6 is a flowchart that illustrates the operation of generating the characteristic impedance value according to some embodiments. FIG. 7 is a flowchart that illustrates the operation of generating the ideal matching circuit according to some embodiments. FIG. 8 is a diagram that illustrates a step of generating a partial matching circuit of FIG. 7.

First, referring to FIG. 5, the impedance matching system 1 according to some embodiments simulates and calculates the characteristic impedance value of the transmission path (S100).

Specifically, referring to FIGS. 1 to 4 and 6, the calculation module 500 sends a command for controlling the simulation module 400 to the simulation module 400 through the communication module 520 (S101), where the command instructs the simulation module 400 to simulate the characteristic impedance value.

In response to the command received from the calculation module 500, the simulation module 400 transmits the information on the entire circuit including the real impedance matching circuit to the calculation module 500 (S102).

The calculation module 500 finds the transmission path in which the real matching circuit is included among the entire system of circuits, that is, a transmission path (analysis path) in which the impedance matching analysis is performed, based on information about the entire system of circuits received from the simulation module 400 and the analysis section 110 that is input by the user (S103).

The calculation module 500 sends a command to the simulation module 400 through the communication module 520 (S104). The command instructs the simulation module 400 to calculate the characteristic impedance value of the transmission path and to perform the impedance matching analysis.

When the user inputs the simulation setting 130, at step S104, the calculation module 500 may send the command that causes the simulation module 400 to simulate only in the section or area corresponding to the simulation setting 130 to calculate the characteristic impedance value.

In response to the command received from the calculation module 500, the simulation module 400 calculates the characteristic impedance value of the transmission path and performs the impedance matching analysis (S105).

Referring to FIG. 5 again, the impedance matching system 1 according to some embodiments generates an ideal matching circuit, using the characteristic impedance value of the transmission path (S200).

The ideal matching circuit may include a circuit in which a plurality of lumped elements (LE) are arranged, for example, arranged in a shunt or a series. The lumped element (LE) may include a capacitor or an inductor. The shunt refers to a case where the lumped elements (LE) are arranged in parallel with the transmission path, and the series refers to a case where the lumped elements (LE) are arranged in series with the transmission path. For example, the ideal matching circuit may include a pi (π) matching circuit in which lumped elements (LE) are arranged in the order of shunt-series-shunt. In another example, the ideal matching circuit may include a T-matching circuit in which the lumped elements (LE) are arranged in the order of series-shunt-series. Hereinafter, the generation of the ideal matching circuit will be specifically described referring to FIG. 7.

Referring to FIGS. 1 to 4, 7 and 8, the ideal matching circuit generation module 530 receives information about the transmission path for performing the impedance matching analysis that was found in step S103 of FIG. 6, and receives the component information 310 of the component connected to the transmission path for performing the impedance matching analysis from the database 300 through the loading module 510 (S201).

The ideal matching circuit generation module 530 divides the transmission path for performing the impedance matching analysis into a first portion P1 and a second portion P2, based on a center of an area (matching circuit area) including the real matching circuit (S202).

The ideal matching circuit generation module 530 receives the characteristic impedance value of the transmission path connected to each of the first portion P1 and the second portion P2 from the simulation module 400 through the communication module 520 (S203).

The ideal matching circuit generation module 530 generates a first partial matching circuit and a second partial matching circuit for each of the first portion P1 and the second portion P2 (S204). For example, the ideal matching circuit generation module 530 may generate the first partial matching circuit and the second partial matching circuit, using an L matching method. In such a case, the first partial matching circuit and the second partial matching circuit may include either an L matching circuit or a reverse L matching circuit, respectively. The L matching circuit may include a circuit in which the lumped elements (LE) are arranged in the order of shunt-series. The reverse L matching circuit may include a circuit in which the lumped elements (LE) are arranged in the order of series-shunt.

Although the embodiment in which the ideal matching circuit generation module 530 generates the first partial matching circuit and the second partial matching circuit using the L matching method was described in step S204, the embodiment is not necessarily limited thereto. For example, the ideal matching circuit generation module 530 may generate the first partial matching circuit and the second partial matching circuit, using the T matching method. In another example, the ideal matching circuit generation module 530 may generate the first partial matching circuit and the second partial matching circuit, using the pi (7c) matching method. The types of matching methods used by the ideal matching circuit generation module 530 may be variously changed in different embodiments.

The ideal matching circuit generation module 530 combines the first partial matching circuit and the second partial matching circuit to generate an ideal matching circuit (S205).

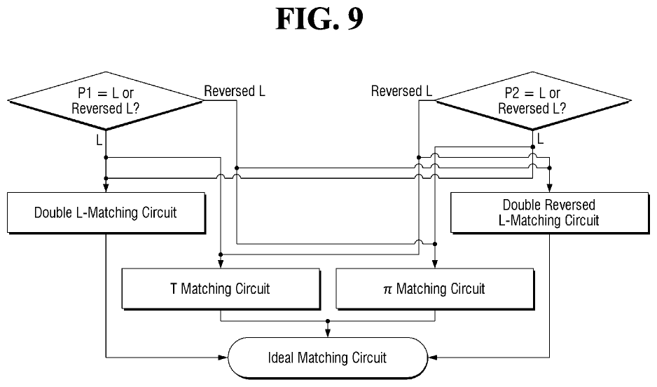

Hereinafter, the ideal matching circuit will be specifically described referring to FIGS. 9 to 13.

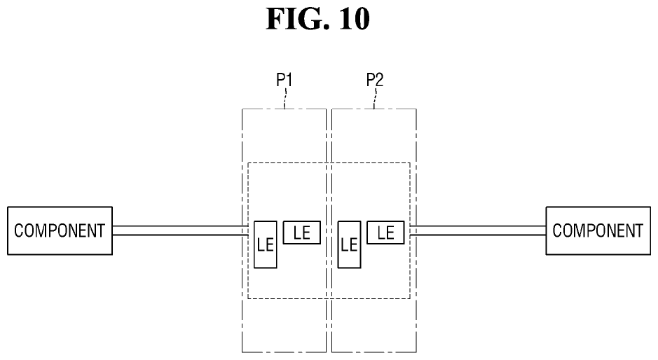

FIG. 9 is a flowchart that illustrates a step of generating the ideal matching circuit of FIG. 7. FIGS. 10 to 13 are diagrams that illustrates the ideal matching circuit.

Referring to FIGS. 9 and 10, when both the first partial matching circuit and the second partial matching circuit are the L matching circuits, the ideal matching circuit generation module 530 combines the first partial matching circuit and the second partial matching circuit to generate an ideal matching circuit that includes a double L matching circuit.

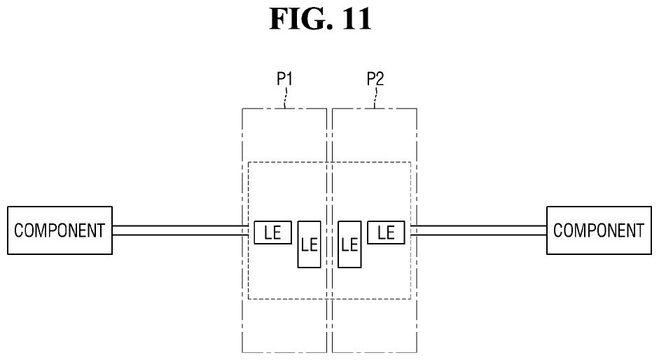

Referring to FIGS. 9 and 11, when the first partial matching circuit includes a reverse L matching circuit, and the second partial matching circuit includes an L matching circuit, the ideal matching circuit generation module 530 combines the first partial matching circuit and the second partial matching circuit to generate an ideal matching circuit that includes the T matching circuit. At this time, the ideal matching circuit generation module 530 may replace the circuit provided by combining the first partial matching circuit and the second partial matching circuit with an equivalent circuit to generate an ideal matching circuit. For example, the ideal matching circuit generation module 530 combines the first partial matching circuit which is the reverse L matching circuit (series-shunt) and the second partial matching circuit which is the L matching circuit (shunt-series), thereby placing two lumped elements (LE), which are continuously arranged in a shunt, into a single lumped element (LE) that is arranged in a shunt.

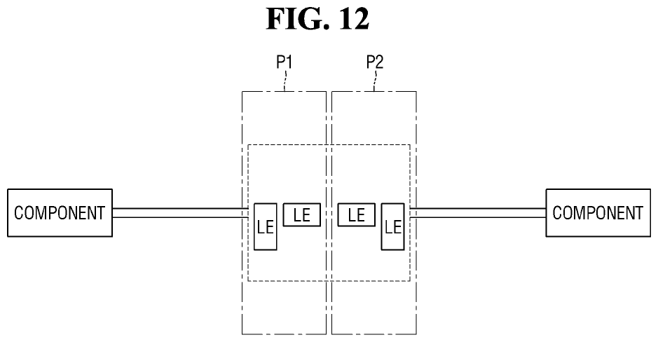

Referring to FIGS. 9 and 12, when the first partial matching circuit includes an L matching circuit and the second partial matching circuit includes a reverse L matching circuit, the ideal matching circuit generation module 530 combines the first partial matching circuit with the second partial matching circuit to generate an ideal matching circuit that includes the pi (7c) matching circuit. At this time, the ideal matching circuit generation module 530 may replace the circuit provided by combining the first partial matching circuit and the second partial matching circuit with an equivalent circuit to generate an ideal matching circuit. For example, the ideal matching circuit generation module 530 may combine the first partial matching circuit which is the L matching circuit (shunt-series) and the second partial matching circuit which is the reverse L matching circuit (series-shunt), thereby placing two lumped elements (LE), which are continuously arranged in a series, in a single lumped element (LE) that is arranged in a series.

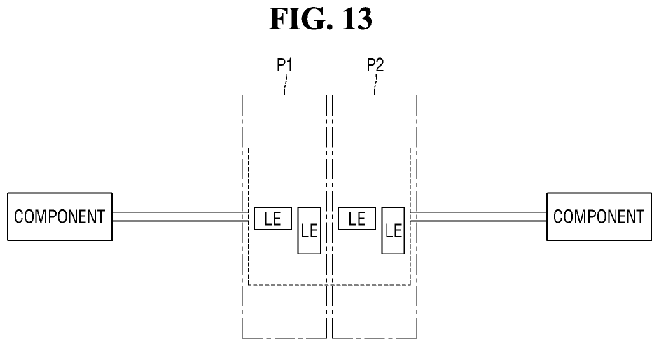

Referring to FIGS. 9 and 13, when both the first partial matching circuit and the second partial matching circuit are the reverse L matching circuit, the ideal matching circuit generation module 530 may combine the first partial matching circuit and the second partial matching circuit to generate an ideal matching circuit that includes the double reverse L matching circuit.

Although an embodiment in which the ideal matching circuit generated in step S205 includes a double L matching circuit, a T matching circuit, a pi (7c) matching circuit or a double reverse L matching circuit was described referring to FIGS. 9 to 13, the embodiment is not necessarily limited thereto. For example, in step S204, when the ideal matching circuit generation module 530 generates the first partial matching circuit and the second partial matching circuit, using the T matching method or the pi (7c) matching method, the ideal matching circuit in which the first partial matching circuit and the second partial matching circuit are combined may include a matching circuit of a newly defined form.

Referring to FIG. 5 again, the impedance matching system 1 according to some embodiments calculates the optimization matching value, using the ideal matching circuit (S300).

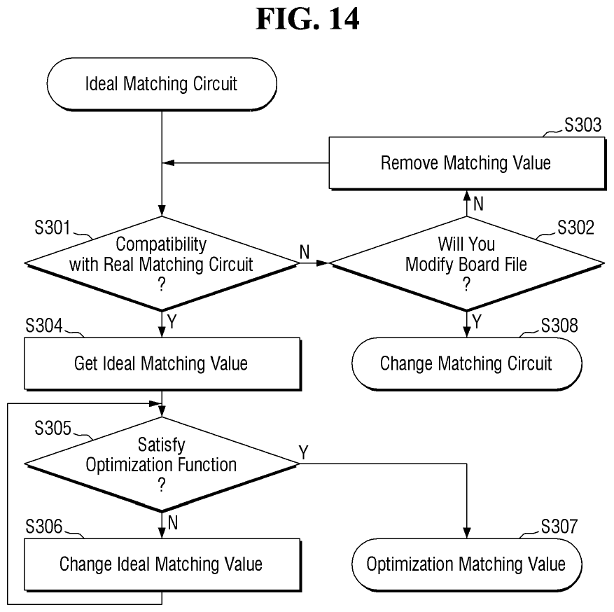

Hereinafter, the calculation of the optimization matching value will be specifically described referring to FIG. 14.

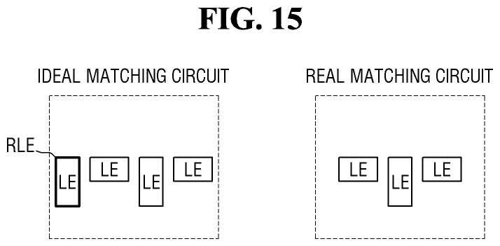

FIG. 14 is a flowchart that illustrates an embodiment of the operation of calculating the optimization matching value according to some embodiments. FIG. 15 is a diagram that illustrates an embodiment of the operation of removing a part of the ideal matching circuit.

Referring to FIGS. 14 and 15, the optimization module 540 determines whether the ideal matching circuit is compatible with the real matching circuit (S301). The compatibility may be determined by whether an ideal matching circuit may be implemented by utilizing the lumped element (LE) placed in a real matching circuit.

If the ideal matching circuit is not compatible with the real matching circuit, the optimization module 540 may receive an input from the user as to whether to change the real matching circuit to the ideal matching circuit (S302). For example, in the ideal matching circuit generation module 530, when the generated ideal matching circuit is a double L matching circuit and the real matching circuit is a T matching circuit, the ideal matching circuit might not be compatible with the real matching circuit. The optimization module 540 may receive an input from the user as to whether to change the T matching circuit to the double L matching circuit.

If the user changes the real matching circuit to the ideal matching circuit, the impedance matching system 1 may receive an input of the board file 120 that includes the changed real matching circuit and starts the impedance matching analysis again (S308). For example, if the T matching circuit is changed to the double L matching circuit, the optimization module 540 stops the optimization matching value calculation, and the impedance matching system 1 may perform the impedance matching analysis from the beginning based on the real matching circuit that includes the double L matching circuit.

If the user does not change the real matching circuit to the ideal matching circuit, the optimization module 540 removes lumped element (LE) having less influence on the impedance matching among the lumped elements (LE) included in the ideal matching circuit (S303). The optimization module 540 removes a part of the lumped element (LE) and determines again whether the generated ideal matching circuit is compatible with the real matching circuit (S301).

Referring to FIG. 15, the optimization module 540 may remove a part of the lumped element (LE) of the ideal matching circuit. For example, when the ideal matching circuit generated by the ideal matching circuit generation module 530 is a double L matching circuit and the real matching circuit is a T matching circuit, the ideal matching circuit might not be compatible with the real matching circuit. Therefore, the optimization module 540 may remove a partial lumped element (RLE of FIG. 15) of the ideal matching circuit so that the ideal matching circuit is compatible with the real matching circuit. For example, the optimization module 540 removes the lumped element (LE) arranged in the series from the ideal matching circuit, which is a double L matching circuit, and may modify the ideal matching circuit to be the same arrangement as the real matching circuit, which is a T matching circuit. Although FIG. 15 shows that the partial lumped element RLE of the double L matching circuit is removed, the embodiment is not necessarily limited thereto. As another example, the optimization module 540 removes a part of the lumped element (LE) from the ideal matching circuit which is a T matching circuit, and may modify the ideal matching circuit so as to be compatible with a real matching circuit that is the pi (7c) matching circuit.

Referring again to FIG. 14, if the ideal matching circuit is compatible with the real matching circuit, the optimization module 540 receives the ideal matching value of the ideal matching circuit (S304).

The optimization module 540 compares the ideal matching value of the ideal matching circuit with the real matching value of the real matching circuit, and determines whether or not the optimization function is satisfied (S305). For example, the optimization module 540 may compare the element value of the lumped element (LE) included in the ideal matching circuit, which is the ideal matching value, with the element value of the lumped element (LE) included in the real matching circuit, which is the real matching value, and may determine whether the optimization function is satisfied.

If the ideal matching value of the ideal matching circuit does not satisfy the optimization function, the optimization module 540 changes the ideal matching value (S306). The changed ideal matching value is compared with the real matching value of the real matching circuit, and it is determined again whether the changed ideal matching value satisfies the optimization function (S305).

If the ideal matching value of the ideal matching circuit satisfies the optimization function, the optimization module 540 calculates the ideal matching value of the ideal matching circuit as the optimization matching value (S307).

The optimization function may be modified in various ways according to the embodiments. For example, the optimization function may calculate the ideal matching value of the ideal matching circuit as the optimization matching value, and may minimize a difference between the ideal matching value of the ideal matching circuit and the real matching value of the real matching circuit.

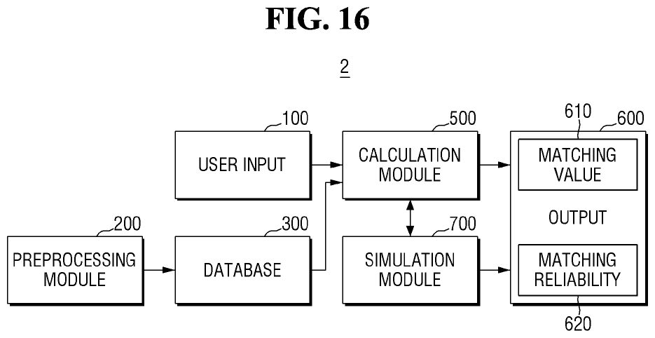

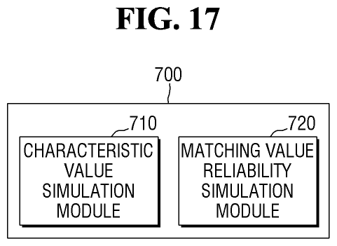

FIG. 16 is a diagram that illustrates an impedance matching automation system according to some embodiments. FIG. 17 is a diagram that illustrates the simulation module of FIG. 16. Hereinafter, for convenience of explanation, components different from those described referring to FIG. 1 will be mainly described.

Referring to FIGS. 16 and 17, an impedance matching automation system 2 may include a preprocessing module 200, a database 300, a simulation module 700, and a calculation module 500.

The simulation module 700 may include a characteristic value simulation module 710 and a matching value reliability simulation module 720.

The characteristic value simulation module 710 may simulate and calculate the characteristic impedance value of a transmission path to which the impedance matching is applied based on the analysis section 110 and the board file 120.

The matching value reliability simulation module 720 applies the optimization matching value calculated by the calculation module 500 to the real matching circuit using the parameter data 320, and may simulate the reliability of the optimization matching value. The matching value reliability simulation module 720 may simulate whether impedance matching is performed well when the received optimization matching value is applied to a real matching circuit.

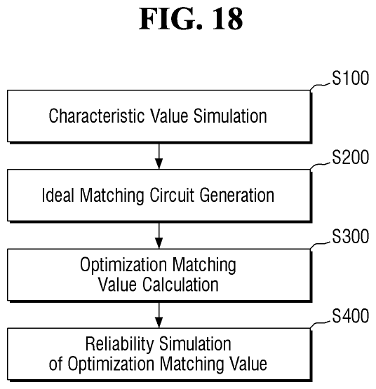

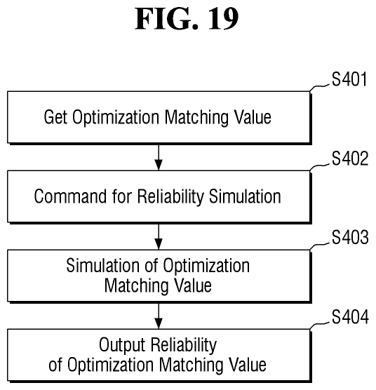

FIG. 18 is a flowchart that illustrates an impedance matching operation according to some embodiments. FIG. 19 is a flowchart that illustrates an operation that simulates the reliability of the optimization matching value of FIG. 18. Hereinafter, points different from those described referring to FIG. 5 will be mainly described for convenience of explanation.

Referring to FIGS. 16 to 18, the impedance matching system 2 according to some embodiments simulates and calculates the characteristic impedance value of the transmission path (S100). Specifically, the characteristic impedance value simulation module 710 may simulate and calculate the characteristic impedance value of the transmission path and performs the impedance matching analysis.

The impedance matching system 2 according to some embodiments generates an ideal matching circuit, using the characteristic impedance value of the transmission path (S200). Specifically, the calculation module 500 may generate an ideal matching circuit, using the characteristic impedance value of the transmission path calculated by the characteristic impedance value simulation module 710.

The impedance matching system 2 according to some embodiments calculates an optimization matching value 610 as a result, e.g. the output 600, using the ideal matching circuit (S300). The operation of the impedance matching system of S100 to S300 is the same as the operation of the impedance matching system 1 of S100 to S300 described above referring to FIG. 5.

The impedance matching system 2 according to some embodiments simulates the reliability of the optimization matching value (S400).

Referring to FIGS. 16, 17 and 19, the matching value reliability simulation module 720 may receive the optimization matching value calculated by the optimization module 540 through the communication module 520 of the calculation module 500 (S401).

The calculation module 500 a command for controlling the matching value reliability simulation module 720 to simulate reliability of the optimization matching value based on the parameter data 320 to the matching value reliability simulation module 720, through the communication module 520 (S402).

The matching value reliability simulation module 720 responds to the commands received through the communication module 520, and applies the optimization matching value to the real matching circuit to simulate reliability (S403).

The matching value reliability simulation module 720 outputs the reliability of the optimization matching value, that is, the matching reliability 620, as a result, e.g. the output 600 (S404). For example, the matching value reliability simulation module 720 may digitize and output a matching degree of impedance when the optimization matching value is applied to a real matching circuit.

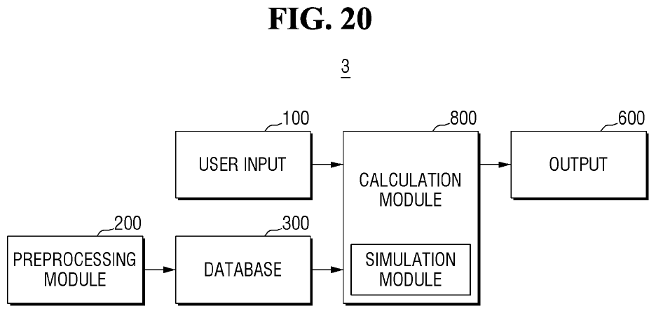

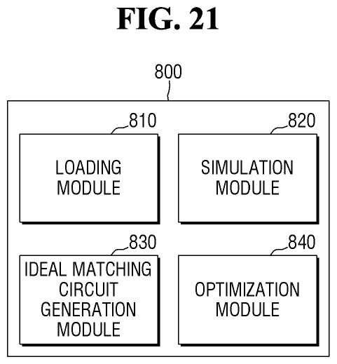

FIG. 20 is a diagram that illustrates an impedance matching automation system according to some embodiments. FIG. 21 is a diagram that illustrates the calculation module of FIG. 20. Hereinafter, for convenience of explanation, points different from those described referring to FIGS. 1 and 4 will be mainly described.

Referring to FIGS. 20 and 21, an impedance matching automation system 3 may include a preprocessing module 200, a database 300, and a calculation module 800.

The calculation module 800 may include a loading module 810, a simulation module 820, an ideal matching circuit generation module 830 and an optimization module 840. The calculation module 800 may include the simulation module 820. In such cases, the compute module 800 might not include a separate communication module for communication with the simulation module 820.

The simulation module 820 may communicate with other configurations of the calculation module 800 inside the calculation module 800 to simulate the reliability of the characteristic impedance value and the optimization matching value of the transmission path.

The methods and systems disclosed herein provide for the automated design of improved matching circuits between components. The methods and systems allow for the production of inter-component circuits with increased reliability and increased impedance matching accuracy.

In concluding the detailed description, those skilled in the art will appreciate that many variations and modifications may be made to the preferred embodiments without substantially departing from the principles of the present invention.

What is claimed is:

1. A method for designing an impedance matching circuit for an input circuit, the method comprising:
receiving a user input identifying a section of the input circuit for matching an impedance to generate a characteristic impedance value;
dividing the section into a first portion and a second portion;
determining a first partial matching circuit of the first portion and a second partial matching circuit of the second portion using component information about electrical components connected to the section and the generated characteristic impedance value; and
combining the first partial matching circuit and the second partial matching circuit to generate an ideal matching circuit.

2. The method of claim 1, wherein the component information is generated by preprocessing a data sheet of the electrical components.

3. The method of claim 1, further comprising:
calculating an optimization matching value using the ideal matching circuit.

4. The method of claim 3, further comprising:
determining a compatibility of the ideal matching circuit to a real matching circuit, and
wherein, when the compatibility is above a threshold value, an optimization function determines an ideal matching value of the ideal matching circuit as the optimization matching value, when a difference between the ideal matching value and the real matching value is minimized.

5. The method of claim 3, further comprising:
determining a compatibility of the ideal matching circuit to a real matching circuit, and
when the compatibility is below a threshold value, changing the real matching circuit to the ideal matching circuit or removing a part of the ideal matching circuit to generate a changed ideal matching circuit.

6. The method of claim 3, further comprising:
applying the optimization matching value to the real matching circuit and simulating matching reliability based on variable information of the characteristic impedance value of the section.

7. The method of claim 1, wherein the determination of the first partial matching circuit and the second partial matching circuit comprises:
calculating the first partial matching circuit of the first portion and the second partial matching circuit of the second portion using an L type matching method,
wherein the first partial matching circuit includes either an L type matching circuit or a reverse L type matching circuit, and
wherein the second partial matching circuit includes either the L type matching circuit or the reverse L type matching circuit.

8. The method of claim 7, wherein the ideal matching circuit includes a double L type matching circuit, a double reverse L type matching circuit, a T type matching circuit, or a pi type matching circuit.

9. The method of claim 1, wherein the user input further includes simulation setting for determining a simulation section, and
the generation of the characteristic impedance value of the simulation section includes simulating only the simulation section based on the simulation setting to generate the characteristic impedance value.

10. An electronic device comprising:
a storage device storing an impedance matching program comprising a set of computer-readable instructions; and
a processor configured to execute the impedance matching program stored in the storage device,
wherein the impedance matching program includes:
a characteristic impedance simulation module configured to parse a user input, the input including an input circuit and identifying a section including a real matching circuit in the input circuit for matching an impedance to determine a characteristic impedance value of the section based on the user input, and
a calculation module configured to calculate an ideal matching circuit, wherein calculating the ideal matching circuit includes:
dividing the section into a first portion and a second portion,
generating a first partial matching circuit of the first portion and a second partial matching circuit of the second portion, using component information of electrical components connected to the section and the characteristic impedance value of the section, and
combining the first partial matching circuit and the second partial matching circuit to calculate the ideal matching circuit.

11. The electronic device of claim 10, wherein the calculation module calculates the first partial matching circuit of the first portion and the second partial matching circuit of the second portion using an L type matching method, and
wherein the ideal matching circuit includes a double L type matching circuit, a double reverse L type matching circuit, a T type matching circuit, or a pi type matching circuit.

12. The electronic device of claim 10, wherein the user input further includes simulation setting for determining a simulation section, and
wherein the characteristic impedance simulation module simulates within the simulation section based on the simulation setting to generate the characteristic impedance value of the simulation section.

13. The electronic device of claim 10, wherein the calculation module determines a compatibility of the ideal matching circuit to the real matching circuit,
and wherein, when the compatibility is above a threshold value, and when an ideal matching value of the ideal matching circuit satisfies an optimization function, the calculation module calculates the ideal matching value of the ideal matching circuit as an optimization matching value indicating an optimized impedance matching between the ideal matching circuit and the real matching circuit, and
wherein, when the ideal matching value of the ideal matching circuit does not satisfy the optimization function, the calculation module changes the ideal matching value of the ideal matching circuit to a changed matching value of the ideal matching circuit and determines whether the changed matching value of the ideal matching circuit satisfies the optimization function.

14. The electronic device of claim 10, wherein the calculation module determines a compatibility of the ideal matching circuit to the real matching circuit,
and wherein, when the compatibility is below a threshold value,
the calculation module either changes the real matching circuit to the ideal matching circuit or removes of a part of the ideal matching circuit to generate a changed ideal matching circuit.

15. The electronic device of claim 10, wherein the impedance matching program further includes a reliability simulation module, wherein the reliability simulation module applies the calculated optimization matching value to a real matching circuit and simulates matching reliability based on variable information of the impedance of the section.

16. A computer program product for designing an impedance matching circuit for an input circuit, the computer program product comprising a computer readable storage medium having program instructions embodied therewith, the program instructions executable by a processor to cause the processor to:
calculate, by a simulation module, a characteristic impedance value of a section including a real matching circuit in an input circuit using information about the section, for matching an impedance; and
calculate, by a calculation module included within an impedance matching program, an optimization matching value,
wherein the calculation of the optimization matching value performed by the calculation module includes:
dividing the section into a first portion and a second portion,
determining a first partial matching circuit of the first portion and a second partial matching circuit of the second portion, using component information about electrical components connected in the section and a characteristic impedance value of the section,
combining the first partial matching circuit and the second partial matching circuit to generate an ideal matching circuit, and
calculating the optimization matching value using the ideal matching circuit and the real matching circuit.

17. The computer-readable recording medium of claim 16, wherein the component information is generated by preprocessing a data sheet of the component.

18. The computer-readable recording medium of claim 16, wherein the calculation module determines a compatibility of the ideal matching circuit to a real matching circuit,
and wherein, when the compatibility is above a threshold value, and when an ideal matching value of the ideal matching circuit satisfies an optimization function, the calculation module calculates the ideal matching value of the ideal matching circuit as an optimization matching value indicating an optimized impedance matching between the ideal matching circuit and the real matching circuit, and
when an ideal matching value of the ideal matching circuit does not satisfy the optimization function, the calculation module changes the ideal matching value of the ideal matching circuit to a changed matching value of the ideal matching circuit and determines whether the changed matching value of the ideal matching circuit satisfies the optimization function.

19. The computer-readable recording medium of claim 16, wherein the calculation module determines a compatibility of the ideal matching circuit to a real matching circuit,
and wherein, when the compatibility is below a threshold value,
the calculation module either changes the real matching circuit to the ideal matching circuit or removes of a part of the ideal matching circuit to generate a changed ideal matching circuit.

20. The computer-readable recording medium of claim 16, wherein the impedance matching program further includes a reliability simulation module which applies the optimization matching value to the real matching circuit and simulates matching reliability.
